(19) United States
(12) Patent Application Publication
(10) Pub. No.: US 2016/0035942 A1
(43) Pub. Date: Feb. 4, 2016

(54) LIGHT-EMITTING APPARATUS HAVING LIGHT-PERVIOUS PLATE

(71) Applicant: PROLIGHT OPTO TECHNOLOGY CORPORATION, TAOYUAN COUNTY (TW)

(72) Inventors: CHEN-LUN HSING CHEN, TAOYUAN COUNTY (TW); JUNG-HAO HUNG, TAOYUAN COUNTY (TW); MENG-TING HSIEH, TAOYUAN COUNTY (TW)

(21) Appl. No.: 14/489,654

(22) Filed: Sep. 18, 2014

(30) Foreign Application Priority Data
Jul. 31, 2014 (TW) 103213549

(51) Int. Cl. H01L 33/48; H01L 33/64; H01L 33/50; H01L 27/15; H01L 33/62

(52) U.S. Cl. CPC H01L 33/486; H01L 27/15; H01L 33/62; H01L 33/50; H01L 33/64

(57) ABSTRACT

The present invention provides a light-emitting apparatus having light-pervious plate. A circuit layer is disposed on a substrate. The circuit layer is adjacent to the LEDs, so that the LEDs can be connected electrically to the circuit layer. In addition, a frame is disposed on the circuit layer. A light-pervious plate is disposed on the frame and located in a light-emitting direction of the LEDs. Moreover, there is a gap between the light-pervious plate and the LEDs.

### FIELD OF THE INVENTION

The present invention relates generally to a light-emitting apparatus, and particularly to a light-emitting apparatus having light-pervious plate.

### BACKGROUND OF THE INVENTION

The invention of electric lamps changes thoroughly the lifestyle of humans. If there were no electric lamps in our lives, all works would be interrupted at night or in bad weather conditions. Given lighting is limited, houses or the lifestyle of humans might be changed radically. People would continue to stay in the primitive era instead of making progresses. Compared with general light bulbs, light-emitting diodes (LEDs) have the advantages of lightness, long lifetime, saving power, fast switching, and high monochromaticity and reliability. Thereby, LEDs have become an indispensable optoelectronic device in daily lives.

In recent years, thanks to the rapid progress in the material technology, the brightness of LEDs is increased continuously, their colors diversified, and their prices lowered, enabling wider applications. The main material for fabricating blue LEDs is gallium nitride (GaN). Although the introduction of blue LEDs happened only in recent years, they have become important devices in the construction of solid-state lighting (SSL). In the trend of saving energy and carbon emission. the LED lighting market expands gradually. They can even replace traditional cold cathode fluorescent lamps. halogen lamps, or incandescent lamps. For example, LEDs can be applied to the backlight modules of liquid crystal displays.

The methods for fabricating modern LEDs are developed progressively, such as front emission LEDs, flip-chip LEDs, and vertical LEDs. No matter what type of LEDs, the packaging method is to fix by using glue and protect LEDs. Nonetheless, according to a general packaging method, a substantial amount of glue is required for fixing and protecting, which leads to high manufacturing cost in the packaging process of light-emitting apparatuses.

The chip-on-board (COB) packaging is a packaging method for LED. The COB packaging is to package multiple LED dies directly on a metal-core printed circuit board having insulation layer, which is different from the packaging method for surface mount device (SMD). The SMD packaging mounts LED dies on a substrate via a frame. The feature of the COB packaging is that the heat generated by LED dies can be transferred to the substrate directly and thus enhancing heat dissipation. In addition, the COB packaging enables plane light emission for LEDs as well as overall design simplification of the light-emitting apparatus.

Nonetheless, when the number of the packaged dies using the COB packaging gets more, the distance among dies gets tight and the power of the whole circuit becomes larger. As the LED dies are placed on the metal-core printed circuit board having insulation layer, it is difficult that the heat generated by the LED dies after light emission is transferred by the metal-core printed circuit board. The heat will accumulate at the dies, which will shorten the lifetime and reduce the performance of the LED dies.

Accordingly, the present invention provides a light-emitting apparatus having light-pervious plate, which is used for fixing and protecting LEDs as well as enhancing heat dissipation.

### SUMMARY

An objective of the present invention is to provide a light-emitting apparatus having light-pervious plate, which is used for protecting LED as well as enhancing heat dissipation.

In order to achieve the objective and effect as described above, the present invention discloses a light-emitting apparatus having light-pervious plate, which comprises a substrate, a circuit layer, at least four LEDs, at least a frame, and a light-pervious plate. The plurality of LEDs and the circuit layer are disposed on the substrate. The frame is disposed on the circuit layer and located on the side of the plurality of LEDs. The light-pervious plate is disposed on the frame and located in a light-emitting direction of the plurality of LEDs. Besides, there is a gap between the light-pervious plate and the plurality of LEDs. By disposing the plurality of LEDs on the substrate directly instead of on the circuit layer, the heat generated by the plurality of LEDs during light emission can be transferred directly from the substrate to the outside, and thus avoiding heat accumulation inside the plurality of LEDs.

### BRIEF DESCRIPTION OF THE DRAWINGS

FIG. 1 shows a structural schematic diagram according to a preferred embodiment of the present invention;

FIG. 2 shows a partial top view of the light-emitting apparatus according to a preferred embodiment of the present invention;

FIG. 3 shows a structural schematic diagram according to another preferred embodiment of the present invention;

FIG. 4 shows a partial top view of the light-emitting apparatus according to another preferred embodiment of the present invention;

FIG. 5 shows a structural schematic diagram according to another preferred embodiment of the present invention; and

FIG. 6 shows a partial top view of the light-emitting apparatus according to another preferred embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

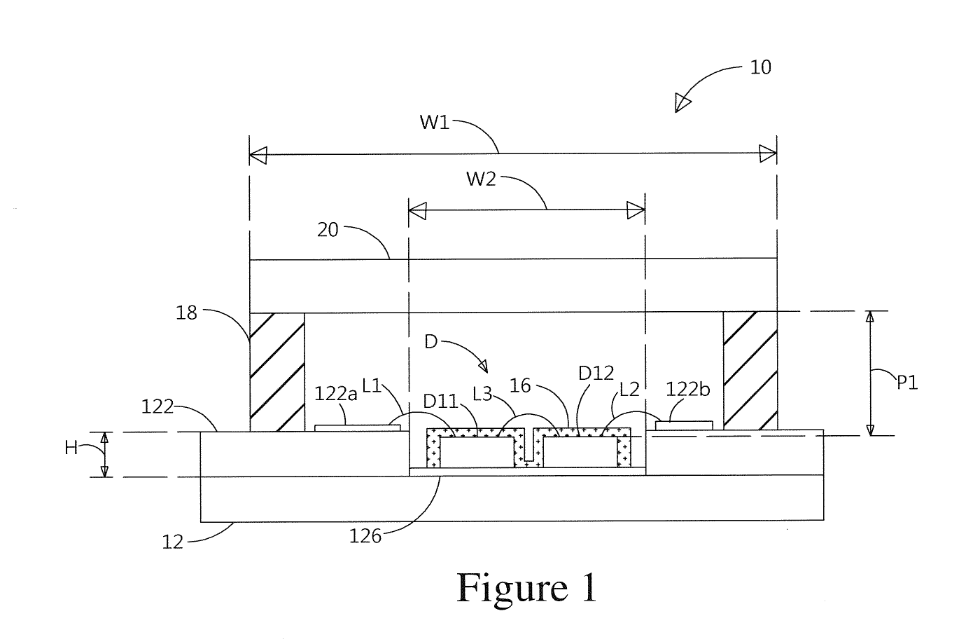

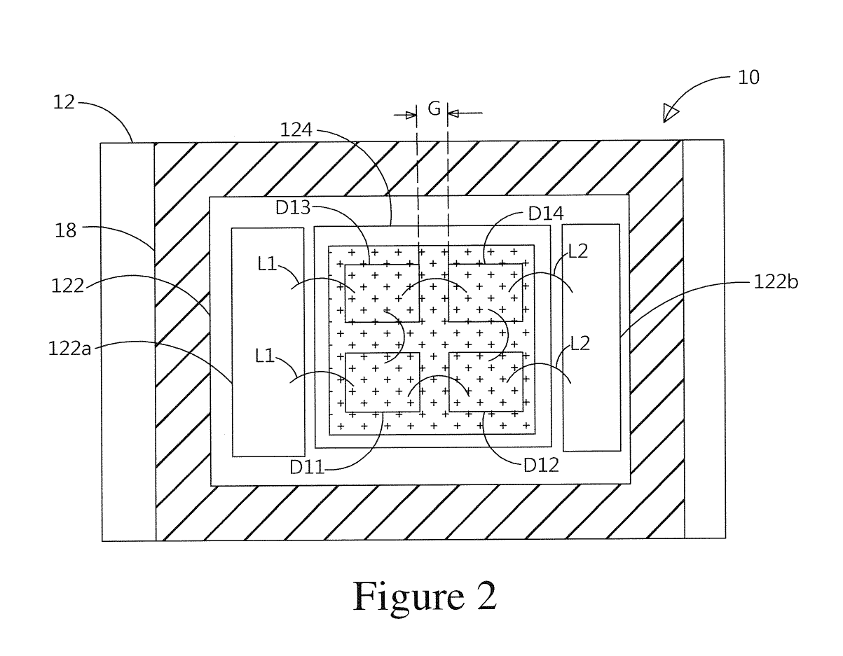

Please refer to FIG. 1 and FIG. 2, which show a structural schematic diagram and a partial top view according to a preferred embodiment of the present invention. As shown in FIG. 1, the light-emitting apparatus 10 according to the present invention comprises a substrate 12, at least four LEDs D, a fluorescent layer 16, a frame 18, and a light-pervious plate 20. The substrate 122 includes a circuit layer 122 thereon. The circuit layer 122 has a penetrating opening 124. The LEDs D according to the present embodiment comprises a first chip D11, a second chip D12, a third chip D13, and a fourth chip D14, which all are front emission LEDs.

The circuit layer 122 is disposed on the substrate 12 and adjacent to the LEDs D. The penetrating opening 124 according to the present embodiment is located at the center of the substrate 12 and exposes the substrate 12. In addition, the penetrating opening 124 can further include an electrically insulating and thermally conductive layer 126. The LEDs D are disposed on the substrate 12 and inside the penetrating opening 124. The electrically insulating and thermally conductive layer 126 is formed by ceramics, such as metal oxides, namely, aluminum oxide or titanium oxide. The circuit layer 122 exposes the substrate 12 via the penetrating opening 124. Because the substrate 12 is a metal substrate, the heat generated by the LEDs D can be transferred outwards directly via the substrate 12 and thus reducing damages of heat on the LEDs D. Thereby, the situations of lifetime reduction or lowered performance of the LEDs D can be avoided, which is beneficial to long-term usage of the LEDs D. The electrically insulating and thermally conductive layer 126 can be further replaced by an electroplating layer, such as gold, silver, nickel, palladium, nickel-gold alloy, or nickel-palladium-gold alloy platings.

As shown in FIG. 2, according to the present embodiment, the first chip D11, the second chip D12, the third chip D13, and the fourth chip D14 are used as examples for the LEDs D. The LEDs D are connected electrically to a first electrical connecting part 122a of the circuit layer 122 via first wires L1 and to a second electrical connecting part 122b of the circuit layer 122 via second wires L2, respectively. Thereby, the first chip D11, the second chip D12, the third chip D13, and the fourth chip D14 are arranged in a matrix. Nonetheless, the invention is not limited to the arrangement. The distribution of the chips can be changed according to requirements. There is a die gap (3 between the first chip D11, the second chip D12, the third chip D13, and the fourth chip D14, respectively. Moreover, the first chip D11, the second chip D12, the third chip D13, and the fourth chip D14 are connected electrically reciprocally via third wires L3. The frame 18 is located on the side of the LEDs D. In other words, it is located on the side of the penetrating opening 124, as shown in FIG. 2. The frame 18 according to the present embodiment surrounds the penetrating opening 124. Nonetheless, the present invention is not limited to the arrangement. The frame 18 can be only disposed on at least one side of the LEDs D. The material of the frame 18 is selected from the group consisting of glass, silica gel, epoxy resin. and polycarbonate.

The fluorescent layer 16 is disposed on the LEDs D, namely, covering the tops and sides of the first chip D11, the second chip D12, the third chip D13, and the fourth chip D14. Nonetheless, the present invention is not limited to the arrangement. Alternatively, the fluorescent layer 16 can cover only the tops of the first chip D11, the second chip D12, the third chip D13, and the fourth chip D14. According to the type of the first chip D11, the second chip D12, the third chip D13, and the fourth chip D14, the fluorescent layer 16 can be changed. For example, if the LEDs Dare blue LEDs, the fluorescent layer 16 will include green and red fluorescent powders. Thereby, the blue light emitted by the LEDs will stimulate the fluorescent layer 16 to emit green and red light. Mixing the red, green, and blue light gives white light. Furthermore, the blue light emitted by the LEDs will stimulate the fluorescent layer 16 to emit yellow light. Mixing the blue and yellow light gives warm white light.

The light-pervious plate 20 is disposed on the frame 18 and above the LEDs D. There is a first gap P1 between the light-pervious plate 20 and the LEDs D for wire bonding. The first gap P1 according to the present embodiment is greater than the height of the penetrating opening 124, and thus providing the space for wire bonding. The material of the light-pervious plate 20 is selected from the group consisting of glass, silica gel, epoxy resin, acrylic (PMMA) and polycarbonate (PC). A first side W1 of the light-pervious plate 20 is greater than a second side W2 of the penetrating opening 124. Besides, the light-pervious plate 20 is above the LEDs D. and thus covering the penetrating opening 124.

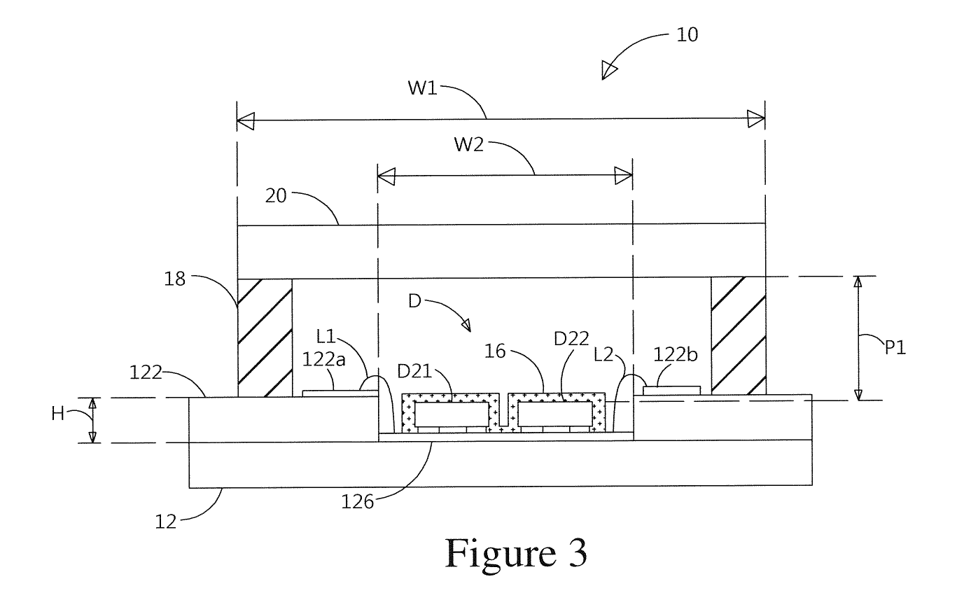

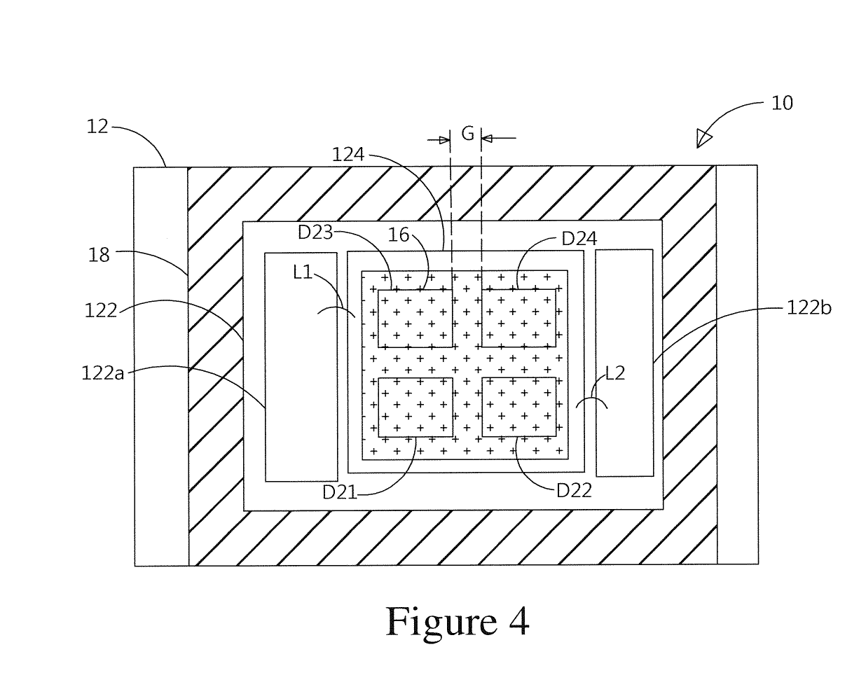

Please refer to FIG. 3 and FIG. 4, which show a structural schematic diagram and a partial top view according to another preferred embodiment of the present invention. The difference between FIG. 1 and FIG. 3 is that the LEDs D in FIG. 1 are front emission LEDs, while the LEDs D in FIG. 3 are flip-chip LEDs. As shown in FIG. 3, the LEDs D according to the present invention are disposed on the substrate 12. Because the LEDs according to the present embodiment are flip-chip LED modules, the first chip D21, the second chip D22, the third chip D23, and the fourth chip D24 are placed inversely on the substrate 12 and inside the penetrating opening 124. Thereby, the first chip D21, the second chip D22, the third chip D23, and the fourth chip D24 are connected electrically to the circuit layer 122 via electrodes, and thereby connected to the external circuitry. The remaining connection relation is identical to the one according to the previous embodiment. Hence, the details will not be described again.

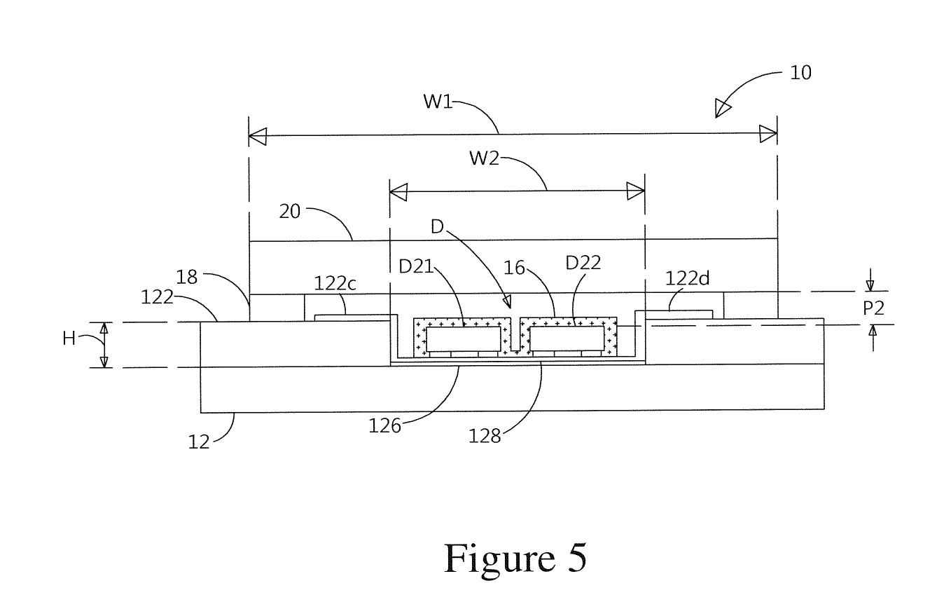

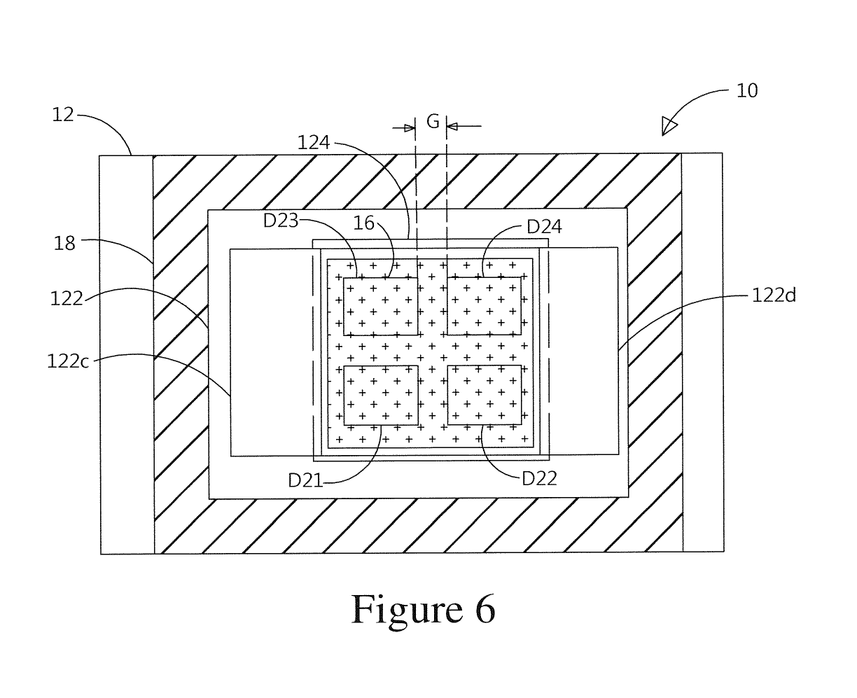

Please refer to FIG. 5 and FIG. 6, which show a structural schematic diagram and a partial top view according to another preferred embodiment of the present invention. The difference between FIG. 3 and FIG. 5 is that the LEDs D in FIG. 3 and FIG. 5 are all flip-chip LEDs. Nonetheless, the LEDs D in FIG. 5 are vertical LEDs. As shown in FIG. 5, the first chip D21, the second chip D22, the third chip D23, and the fourth chip D24 of the LEDs D according to the present invention are disposed on the substrate 12 and inside the penetrating opening 124. Because the first chip D21, the second chip D22, the third chip D23, and the fourth chip D24 according to the present embodiment are flip-chip LEDs, they are connected electrically to the substrate via the electrodes at their bottom. The third electrical connecting part 122c and the fourth electrical connecting part 122d extend to the penetrating opening 124 and form a conductive part 128 on the electrically insulating and thermally conductive layer 126. The first chip D21, the second chip D22, the third chip D23, and the fourth chip D24 are connected electrically to the third and fourth electrical connecting parts 122c, 122d through the conductive part 128 and thus to the external circuitry.

The first chip D21, the second chip D22, the third chip D23, and the fourth chip D24 require no first and second wires for connecting to the external circuitry. There is a second gap P2 between the LEDs D and the light-pervious plate 20 and smaller than the height H of the penetrating opening 124. The remaining connection relation is identical to the one according to the previous embodiment. Hence, the details will not be described again.

To sum up, the present invention provides a light-emitting apparatus having light-pervious plate. According to the invention, the LEDs are disposed on the substrate and inside the penetrating opening. The light-pervious plate is disposed above the LEDs, so that the light of the LEDs can emit outwards through the light-pervious plate. In addition, because the LEDs are disposed on the substrate directly, heat can be dissipated via the substrate directly.

Accordingly, the present invention conforms to the legal requirements owing to its novelty, nonobviousness, and utility. However. the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A light-emitting apparatus having light-pervious plate, comprising:
a substrate;
a circuit layer, disposed on said substrate;
at least four light-emitting diodes, disposed on said substrate and adjacent to said circuit layer, and coupled to said circuit layer;
a frame, disposed on said circuit layer and located on the side of said plurality of light-emitting diodes; and
a light-pervious plate, disposed on said frame, located in a light-emitting direction of said plurality of light-emitting diodes, including a gap between said light-pervious plate and said plurality of light-emitting diodes, and the distance between said plurality of light-emitting diodes not greater than 400 micrometers;
wherein said circuit layer includes a penetrating opening to expose a portion of said substrate; said plurality of light-emitting diodes are disposed in said penetrating opening, and the height of said plurality of light-emitting diodes is smaller than the height of said penetrating opening.

2. The light-emitting apparatus of claim 1, wherein said circuit layer is located on the side of said penetrating opening.

3. The light-emitting apparatus of claim 2, wherein a first side of said light-pervious plate is greater than a second side of said penetrating opening and said light-pervious plate covers said penetrating opening.

4. The light-emitting apparatus of claim 2, wherein the distance between said substrate and said light-pervious plate is greater than or equal to the height of said penetrating opening.

5. The light-emitting apparatus of claim 2, wherein the distance between said plurality of light-emitting diodes and said light-pervious plate is smaller than the height of said penetrating opening.

6. The light-emitting apparatus of claim 1, and further comprising a fluorescent layer, disposed between said plurality of light-emitting diodes and said light-pervious plate, and covering said plurality of light-emitting diodes.

7. The light-emitting apparatus of claim 1, wherein said substrate is a metal substrate; an electrically insulating and thermally conductive layer is disposed between said substrate and said plurality of light-emitting diodes; and
said substrate and said electrically insulating and thermally conductive layer transfer the heat generated by said plurality of light-emitting diodes.

8. The light-emitting apparatus of claim 1, wherein said substrate is a metal substrate; and an electroplating layer is disposed between said substrate and said plurality of light-emitting diodes.

9. The light-emitting apparatus of claim 1, wherein said plurality of light-emitting diodes are flip-chip light-emitting diodes; and a conductive part is further included between said plurality of light-emitting diodes and said electrically insulating and thermally conductive layer for connected electrically said plurality of light-emitting diodes and said circuit layer.
